(19) United States
(12) Patent Application Publication
(10) Pub. No.: US 2025/0369700 A1
(43) Pub. Date: Dec. 4, 2025

(54) VAPOR CHAMBER AND ELECTRONIC DEVICE INCLUDING THE SAME

(71) Applicant: Samsung Display Co., LTD., Yongin-si (KR)

(72) Inventors: Byoungkyoo Park, Yongin-si (KR); WAN-SANG KIM, Yongin-si (KR); WEE-JOON JEONG, Yongin-si (KR); Jangun Choi, Yongin-si (KR)

(21) Appl. No.: 19/082,086

(22) Filed: Mar. 17, 2025

(30) Foreign Application Priority Data
Jun. 4, 2024 (KR) 10-2024-0072885

(51) Int. Cl. F28D 15/04; H05K 7/20

(52) U.S. Cl. CPC F28D 15/04; H05K 7/2099

(57) ABSTRACT

A vapor chamber includes: a front surface member including a first layer and a second layer on a first surface of the first layer, the second layer including a material different from a material of the first layer; a rear surface member coupled to the front surface member and including a third layer and a fourth layer, the third layer having a first surface facing a first surface of the first layer, the fourth layer being on the first surface of the third layer and including a material different from a material of the third layer; a wick between the front surface member and the rear surface member; and a refrigerant at least partially filling an area between the front surface member and the rear surface member.

### CROSS-REFERENCE TO RELATED APPLICATION

The present application claims priority to and the benefit of Korean Patent Application No. 10-2024-0072885, filed on Jun. 4, 2024, in the Korean Intellectual Property Office, the entire disclosure of which is incorporated herein by reference.

### BACKGROUND

### 1. Field

Aspects of embodiments of the present disclosure relate to a vapor chamber and an electronic device including the vapor chamber.

### 2. Description of the Related Art

Flat panel display devices are replacing cathode ray tube (CRT) display devices due to their lightweight and thin characteristics. As representative examples of such flat panel display devices, there are liquid crystal display devices and organic light emitting diode display devices.

A display device may include a heat dissipation member for efficiently dissipating heat generated when the display panel emits light. The display device may include a vapor chamber including a refrigerant, such as a phase change material (PCM), which acts as the heat dissipation member.

### SUMMARY

Embodiments of the present disclosure provide a vapor chamber with improved heat dissipation performance.

Embodiments of the present disclosure also provide an electronic device including the display device.

Additional aspects and features of the present disclosure will be set forth in the description that follows and, in part, will be apparent from the description or may be learned by practice of described embodiments of the present disclosure.

A vapor chamber, according to an embodiment of the present disclosure, includes a front surface member including a first layer and a second layer on a first surface of the first layer, the second layer including a material different from a material of the first layer; a rear surface member coupled to the front surface member and including a third layer and a fourth layer, the third layer having a first surface facing the first surface of the first layer, the fourth layer being on the first surface of the third layer and including a material different from a material of the third layer; a wick between the front surface member and the rear surface member; and a refrigerant at least partially filling an area between the front surface member and the rear surface member.

In an embodiment, a thickness of the second layer may be less than a thickness of the first layer, and a thickness of the fourth layer may be less than a thickness of the third layer.

In an embodiment, each of the first layer and the third layer may include a polymer or a composite material, and each of the second layer and the fourth layer may include a metal or an alloy.

In an embodiment, the first surface of the third layer may have a flat portion and a convex portion convex toward the wick from the flat portion.

In an embodiment, the fourth layer may extend along a profile of the first surface of the third layer.

In an embodiment, the fourth layer may be in point contact with the wick.

In an embodiment, the convex portion may have a half-spherical shape or an elliptical half-spherical shape convex toward the wick.

In an embodiment, the fourth layer may be in line contact with the wick.

In an embodiment, the convex portion may have a half-cylindrical shape or an elliptical half-cylindrical shape convex toward the wick.

In an embodiment, the third layer may have a second surface opposite to the first surface. The second surface of the third layer may have a flat portion and a concave portion concave toward the first surface of the third layer from the flat portion corresponding to the convex portion.

In an embodiment, the third layer may have a second surface opposite to the first surface. The second surface of the third layer may be flat.

In an embodiment, the first layer may have a second surface opposite to the first surface. The first surface of the first layer may have a flat portion and a concave portion concave toward the second surface of the first layer from the flat portion corresponding to the convex portion of the third layer.

In an embodiment, a curvature radius of the convex portion of the third layer may be less than a curvature radius of the concave portion of the first layer.

In an embodiment, each of the second layer and the wick may extend along a profile of the first surface of the first layer.

In an embodiment, the first layer may have a second surface opposite to the first surface. The second surface of the first layer may be flat.

In an embodiment, the vapor chamber may further include a reinforcing member between the wick and the rear surface member, and the reinforcing member may include a wire mesh.

A vapor chamber, according to another embodiment of the present disclosure, includes a front surface member including a first layer and a second layer on the first layer, the second layer including a material different from a material of the first layer; a rear surface member coupled to the front surface member and including a metal or an alloy, the rear surface member having wrinkled portions, the wrinkled portions each extending a first direction and arranged along a second direction perpendicular to the first direction; a wick between the front surface member and the rear surface member; a reinforcing member between the wick and the rear surface member; and a refrigerant at least partially filling an area between the front surface member and the rear surface member.

In an embodiment, the second layer may include a metal or an alloy. A thickness of the rear surface member may be greater than a thickness of the second layer.

In an embodiment, the first layer may have a first surface facing the rear surface member and a second surface opposite to the first surface. The rear surface member may have a first surface facing the front surface member and a second surface opposite to the first surface. The second surface of the first layer may be flat. Each of the first surface and the second surface of the rear surface member may be curved.

An electronic device, according to an embodiment of the present disclosure, includes a display device including a display panel and a vapor chamber and a power supply configured to provide power to the display device. The display panel has a first surface for displaying an image and a second surface opposite to the first surface, and the vapor chamber is on the second surface of the display panel. The vapor chamber includes a front surface member including a first layer and a second layer on a first surface of the first layer, the second layer including a material different from a material of the first layer; a rear surface member coupled to the front surface member and including a third layer and a fourth layer, the third layer having a first surface facing the first surface of the first layer, the fourth layer being on the first surface of the third layer and including a material different from a material of the third layer; a wick between the front surface member and the rear surface member; and a refrigerant at least partially filling an area between the front surface member and the rear surface member.

According to embodiments of the present disclosure, a vapor chamber is provided that can be bent in at least one direction. Accordingly, the vapor chamber may be attached to a large-area display panel without an air gap by a lamination process using a roller, or the like. Therefore, a manufacturing cost of the display device may be reduced, and the heat dissipation performance of the vapor chamber may be improved so that a reliability of the display device may be improved.

It is to be understood that both the foregoing general description and the following detailed description are exemplary and explanatory and are intended to provide further explanation of the present disclosure as claimed.

### BRIEF DESCRIPTION OF THE DRAWINGS

The accompanying drawings, which are included to provide a further understanding of the present disclosure and are incorporated in and constitute a part of this specification, illustrate embodiments of the present disclosure, and together with the description, explain aspects and features of the present disclosure.

FIG. 1 is an exploded perspective view of a display device according to an embodiment.

FIG. 2 is a front view of a display device according to an embodiment.

FIG. 3 is a rear view of a display device according to an embodiment.

FIG. 4 is a side view of a display device according to an embodiment.

FIG. 5 is a cross-sectional view of a display panel according to an embodiment.

FIG. 6 is a cross-sectional view of a vapor chamber according to an embodiment.

FIGS. 7 and 8 are perspective views of a rear surface member included in the vapor chamber shown in FIG. 6 according to various embodiments.

FIG. 9 is a cross-sectional view of a vapor chamber according to another embodiment.

FIG. 10 is a cross-sectional view of a vapor chamber according to another embodiment.

FIG. 11 is a cross-sectional view of a vapor chamber according to another embodiment.

FIGS. 12 and 13 are views of a reinforcing member included in the vapor chamber shown in FIG. 11 according to various embodiments.

FIG. 14 is a cross-sectional view of a vapor chamber according to another embodiment.

FIG. 15 is a block diagram describing an electronic device according to an embodiment.

### DETAILED DESCRIPTION

Various embodiments will be described more fully hereinafter with reference to the accompanying drawings, in which some embodiments are shown. The present disclosure may, however, be embodied in many different forms and should not be construed as limited to the embodiments set forth herein. Rather, these embodiments are provided so that this disclosure will be thorough and complete and will fully convey the present disclosure to those skilled in the art.

In the disclosure, various modifications can be made, various forms can be used, and specific embodiments will be illustrated in the drawings and described in detail in the text. However, this is not intended to limit the present disclosure to a specific form disclosed, and it will be understood that all changes, equivalents, or substitutes which fall in the spirit and technical scope of the present disclosure should be included.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Hereinafter, embodiments of the present disclosure will be described, in detail, with reference to the accompanying drawings. The same reference numerals are used for the same components in the drawings, and redundant descriptions of the same components may be omitted or only briefly repeated.

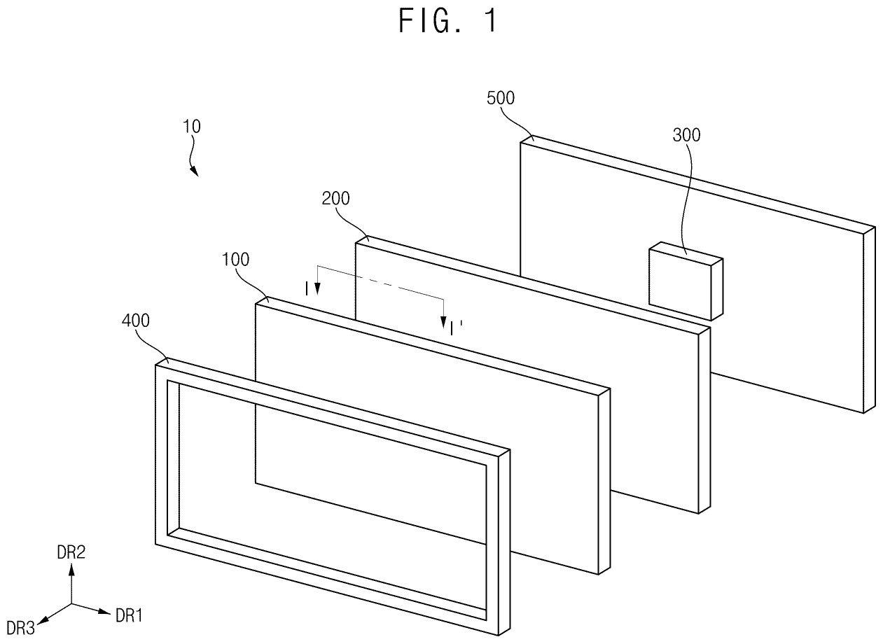

FIG. 1 is an exploded perspective view of a display device according to an embodiment.

Referring to FIG. 1, a display device 10, according to an embodiment, may be various types of display device, such as a television, a monitor, a tablet PC, a smartphone, an external billboard, an electric signboard, or the like. For example, aspects of the present disclosure may be more usefully applied to a large-area display device, such as a television or the like. Hereinafter, although a television will be described as an example of the display device 10, embodiments of the present disclosure are not limited thereto.

In an embodiment, the display device 10 may include a display panel 100, a vapor chamber 200, a driving board 300, a front cover 400, and a rear cover 500.

The display panel 100 may display an image. The display panel 100 may be a self-light emitting display panel. For example, the display panel 100 may be an organic light emitting display panel, but this is an example and embodiments are not limited thereto. For other examples, the display panel 100 may be an inorganic light emitting display panel, a quantum dot light emitting display panel, a micro LED display panel, a nano LED display panel, a liquid crystal display panel, or the like.

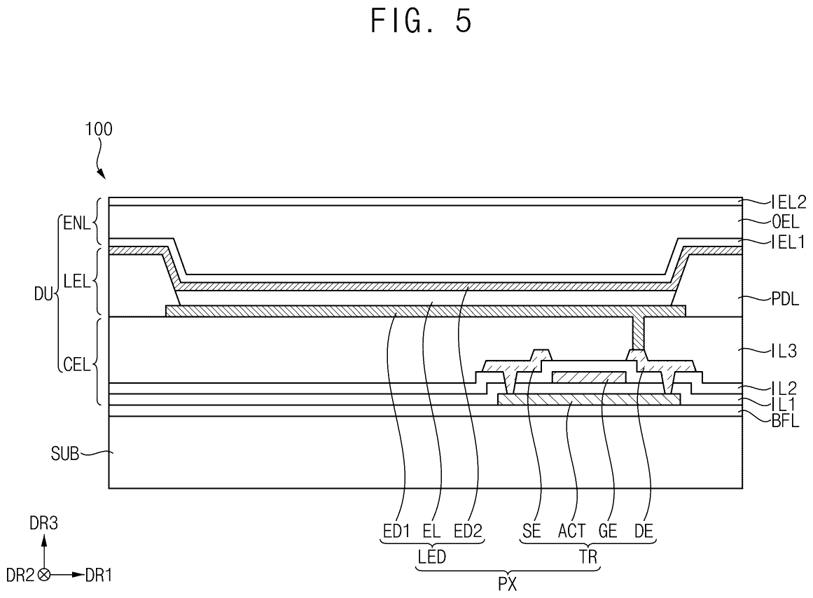

The display panel 100 (or the display device 10) may display an image on a display surface. In an embodiment, the display surface may be substantially parallel to a plane defined by a first direction DR1 and a second direction DR2 crossing the first direction DR1. For example, the second direction DR2 may be perpendicular to the first direction DR1. The display panel 100 may display the image in a third direction DR3 from (or on) the display surface. The third direction DR3 may be substantially parallel to a normal direction of the plane defined by the first direction DR1 and the second direction DR2. The display surface may correspond to a front surface (e.g., a first surface 100a in FIG. 4) of the display panel 100. Hereinafter, the third direction DR3 may be referred to as a front direction, and a direction opposite to the third direction DR3 may be referred to as a rear direction.

In another embodiment, the display panel 100 may be a curved display panel having a curved display surface that displays an image. For example, the curved display surface of the display panel 100 may be convex in the third direction DR3 or may be concave in the direction opposite to the third direction DR3. Hereinafter, embodiments in which the display surface is flat and substantially parallel to a plane defined by the first direction DR1 and the second direction DR2 will be described (see, e.g., FIG. 1), but the present disclosure is not limited thereto.

The vapor chamber 200 may be disposed on a rear surface (e.g., a second surface 100b in FIG. 4) of the display panel 100 opposite to the display surface of the display panel 100. The vapor chamber 200 may dissipate heat generated in (or by) the display panel 100 and the driving board 300 to another space inside the display device 10 or to the outside of the display device 10. For example, the vapor chamber 200 may dissipate the heat generated in the display panel 100 and the driving board 300 to an internal space of the front cover 400 or the rear cover 500 or to outside of the display device 10.

The driving board 300 may include a processor, a memory, a battery, or the like. For example, the processor may include one or more of a central processing unit, an application processor, a graphics processing unit, an image signal processor, a sensor hub processor, a communication processor, or the like. In an embodiment, the processor may be mounted in (or on) an electronic component, such as an integrated circuit chip, and disposed on the driving board 300.

Electronic components may be disposed on the driving board 300, and some of the electronic components, such as the integrated circuit chip in which the processor is mounted, may generate heat while operating. Heat generated by the electronic component may degrade operating performance of the electronic component itself and/or power efficiency of the display device 10.

The driving board 300 may be disposed on a rear surface of the vapor chamber 200. The driving board 300 may be spaced apart from the display panel 100 with the vapor chamber 200 interposed therebetween. When the heat generated from the driving board 300 is transmitted to the display panel 100, luminous efficiency of the display panel 100 may be reduced or a burn-in phenomenon of an emission layer of an organic light emitting element may be generated (or accelerated). The display device 10 may include a heat dissipation member, such as the vapor chamber 200, to quickly disperse or dissipate the heat generated from the driving board 300.

The front cover 400 and the rear cover 500 may be adjacent to (e.g., surround) the display panel 100, the vapor chamber 200, and the driving board 300. The front cover 400 and the rear cover 500 may protect the display panel 100, the vapor chamber 200, and the driving board 300 from external impacts or the like.

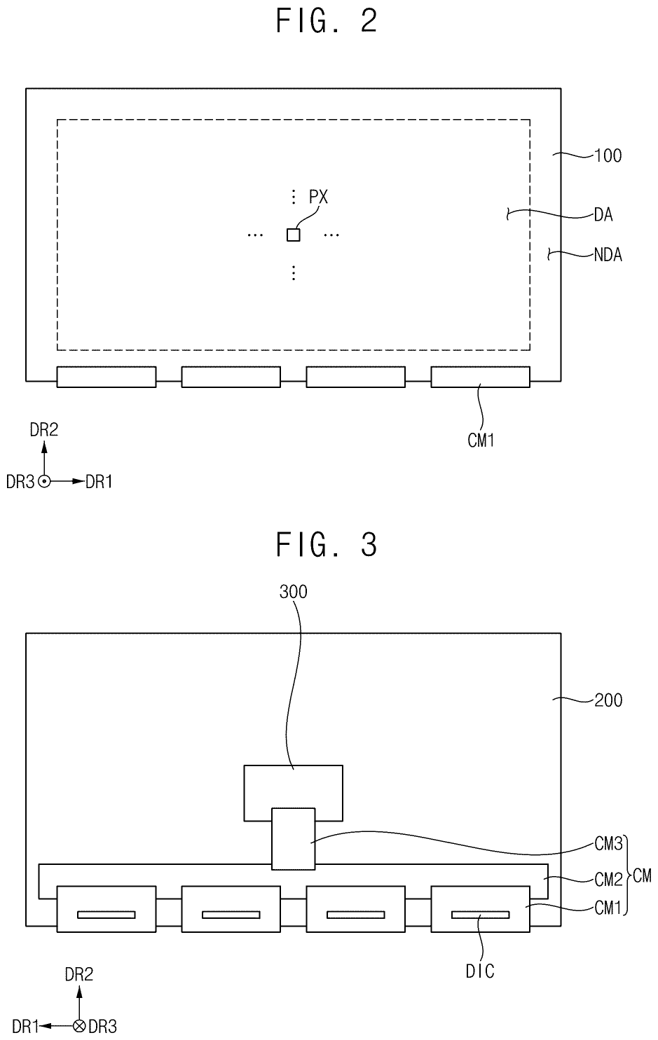

In the embodiment illustrated in FIG. 1, the front cover 400 may define (or may have) an opening overlapping a display area (e.g., a display area DA in FIG. 2) of the display surface of the display panel 100.

In another embodiment, the front cover 400 may cover the entire display surface of the display panel 100. The front cover 400 may have light-transmitting properties so that light emitted from the display panel 100 may pass therethrough. For example, the front cover 400 may include a transparent polymer resin, such as polyimide or glass.

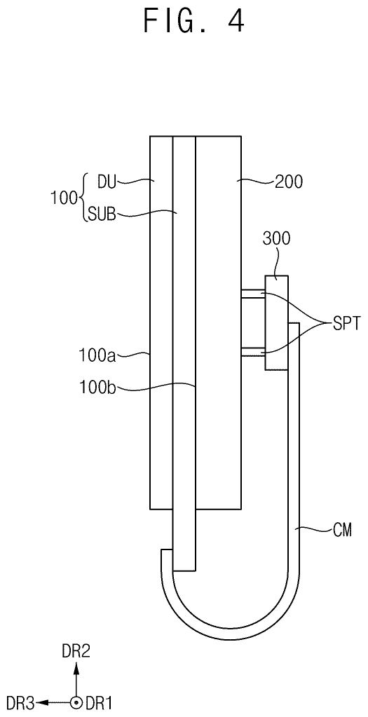

FIG. 2 is a front view of a display device according to an embodiment. FIG. 3 is a rear view of a display device according to an embodiment. FIG. 4 is a side view of a display device according to an embodiment.

For convenience of description, the front cover 400 and the rear cover 500 shown in FIG. 1 are omitted in FIGS. 2 to 4.

Referring to FIGS. 2 to 4, the display panel 100 may have a first surface 100a and a second surface 100b opposite to the first surface 100a. The first surface 100a may be a front surface of the display panel 100, and the second surface 100b may be a rear surface of the display panel 100. The display panel 100 may display the image in the third direction DR3 on (or from) the first surface 100a. The first surface 100a of the display panel 100 may be the display surface.

The display panel 100 may include a substrate SUB and a display layer DU. The display panel 100 (or the substrate SUB) may have a display area DA at where an image is displayed and a non-display area NDA where an image is not displayed. The display layer DU may include a plurality of pixels PX for generating the image. For example, the pixels PX may be disposed in a matrix form along the first direction DR1 and the second direction DR2 in the display area DA, but embodiments are not limited thereto.

Each of the pixels PX may include a pixel circuit and a light emitting element. The pixel circuit may include at least one thin film transistor and at least one capacitor. The thin film transistor may generate a driving current and may provide the generated driving current to the light emitting element. The light emitting element may emit light based on (or according to) the driving current. For example, the light emitting element may include (or may be) an organic light emitting diode, an inorganic light emitting diode, a quantum dot light emitting diode, a micro light emitting diode, a nano light emitting diode, or the like. The image may be generated by combining light emitted from each of the pixels PX.

The non-display area NDA may be outside of the display area DA. For example, the non-display area NDA may surround (or may extend around) the display area DA in a plan view. Driving circuits for driving the display area DA or transfer lines may be disposed in the non-display area NDA. For example, a pad portion including a plurality of pads and electrically connected to the display area DA may be disposed in the non-display area NDA. In an embodiment, the pad portion may be provided in plurality.

A circuit member CM may connect the display panel 100 and the driving board 300 to each other. In an embodiment, the circuit member CM may include a first circuit member CM1, a second circuit member CM2, and a third circuit member CM3.

In an embodiment, the first circuit member CM1 may be provided in plurality. The first circuit members CM1 may be arranged in the first direction DR1. A first end portion of each of the first circuit members CM1 may be connected to the non-display area NDA on a front surface of the substrate SUB. The first end portion of each of the first circuit members CM1 may be electrically connected to the pad portion. A second end portion, opposite to the first end portion, of each of the first circuit members CM1 may be connected to the second circuit member CM2.

The first circuit member CM1 may be a flexible member, for example, a connecting film or a flexible circuit board. As illustrated in FIGS. 2 to 4, the first circuit member CM1 may be bent such that the second circuit member CM2, the third circuit member CM3, and the driving board 300 may be positioned on the second surface 100b of the display panel 100 (e.g., at the rear of the display panel 100). The second circuit member CM2, the third circuit member CM3, and the driving board 300 may be positioned at the rear of the vapor chamber 200.

In an embodiment, driving chips DIC may be mounted on the first circuit member CM1 by a chip on film (COF) method. However, this is merely an example, and embodiments are not limited thereto. In another embodiment, the driving chips DIC may be directly mounted on the display panel 100 by a chip on glass (COG) method. In other embodiments, some of the driving chips DIC (e.g., data driving chips) may be mounted on the first circuit member CM1 and the others (e.g., scan driving chips) may be mounted on the display panel 100.

The second circuit member CM2 may be connected to the first circuit members CM1 and the third circuit member CM3. In an embodiment, the second circuit member CM2 may extend in the first direction DR1. For example, the second circuit member CM2 may be a printed circuit board.

The third circuit member CM3 may be connected to the second circuit member CM2 and the driving board 300. In an embodiment, the third circuit member CM3 may extend in the second direction DR2. For example, the third circuit member CM3 may be a line connection film.

The first circuit member CM1 may be bent such that the driving board 300 may be positioned at the rear of the vapor chamber 200. The driving board 300 may be spaced apart from the display panel 100 with the vapor chamber 200 interposed therebetween. In an embodiment, the driving board 300 may be supported and fixed while being spaced apart from the vapor chamber 200 by supporters SPT disposed between the vapor chamber 200 and the driving board 300. In another embodiment, the supporters SPT may be omitted, and the driving board 300 may be disposed directly on the rear surface of the vapor chamber 200.

The vapor chamber 200 may be disposed on the second surface 100b of the display panel 100. The vapor chamber 200 may dissipate the heat generated by (or in) the display panel 100 and the driving board 300 to another space inside the display device 10 or to outside of the display device 10.

In an embodiment, the vapor chamber 200 may be flexible. Heat may be generated from the entire display panel 100, and the vapor chamber 200 should therefore be attached to the second surface 100b of the display panel 100 to cover most of the display panel 100. In addition, when an air gap is formed between the display panel 100 and the vapor chamber 200, the heat dissipation efficiency may be significantly reduced, so the vapor chamber 200 should be attached to the display panel 100 without an air gap.

The display panel 100 may be a large-area rigid display panel. In such an embodiment, according to a comparative example in which the vapor chamber is rigid, the rigid vapor chamber may be attached to the second surface 100b of the display panel 100 by using a thermally conductive tape including a thermal interface material (TIM). According to embodiments of the present disclosure, when the thermally conductive tape is attached to the entire large-area display panel 100 to attach the rigid vapor chamber to the display panel 100 without an air gap, a manufacturing cost of the display device may increase due to the high cost of the thermal interface material. When a small amount of the thermally conductive tape is partially attached to the large-area display panel 100 to reduce the cost, an air layer may exist (or may be formed) in an area where the thermally conductive tape is not attached, and a temperature of the area may increase (or continuously increase). Therefore, deterioration of elements in the area may be generated (or accelerated), and reliability of the display device may be reduced.

According to embodiments, the vapor chamber 200 may be flexible. For example, the vapor chamber 200 may be flexible so that it can be bent in at least one direction (e.g., in the first direction DR1 and/or the second direction DR2). Accordingly, the vapor chamber 200 may be attached to the entire second surface 100b of the display panel 100 without an air gap by a lamination process using a roller, or the like. Accordingly, the manufacturing cost of the display device 10 may be reduced, the heat dissipation efficiency of the vapor chamber 200 may be improved, and the reliability of the display device 10 may be improved.

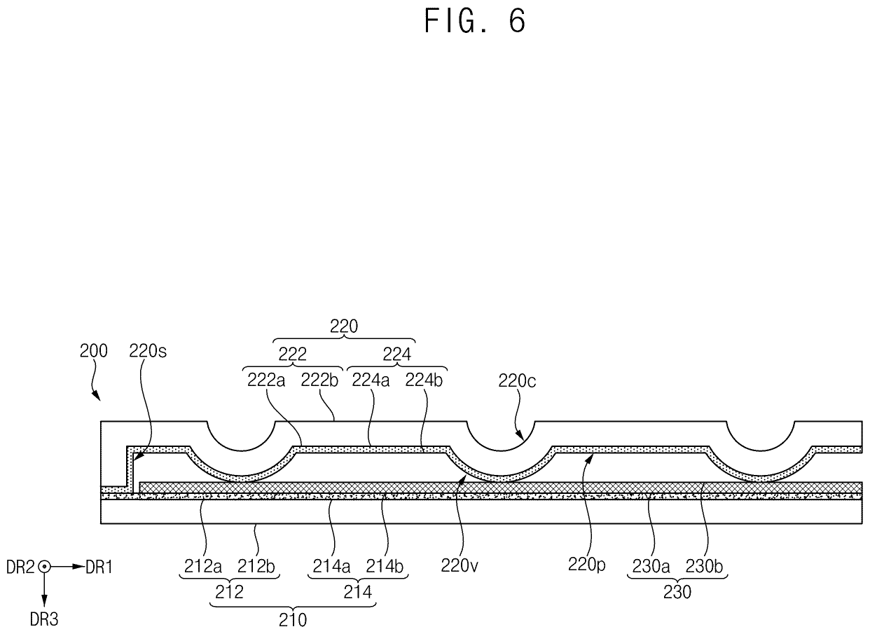

FIG. 5 is a cross-sectional view of a display panel according to an embodiment. In particular, FIG. 5 is a cross-sectional view of the display area DA of the display panel 100 described above.

Referring to FIG. 5, the display panel 100 may include a substrate SUB and a display layer DU. In an embodiment, the display layer DU may include a circuit element layer CEL, a light emitting element layer LEL, and an encapsulation layer ENL.

The substrate SUB may be an insulating substrate formed of a transparent or opaque material. In an embodiment, the substrate SUB may be a rigid substrate including a material such as glass, quartz, or the like. The display panel 100 may be a rigid display panel.

The buffer layer BFL may be disposed on the substrate SUB. The buffer layer BFL may prevent or reduce impurities, such as oxygen or moisture, from penetrating into an upper portion of the substrate SUB through the substrate SUB. The buffer layer BFL may include an inorganic insulating material, such as a silicon compound, a metal oxide, or the like. For example, the buffer layer BFL may include silicon oxide (SiOₓ), silicon nitride (SiNₓ), silicon oxynitride (SiOₓN_{y}), silicon oxycarbide (SiOₓC_{y}), silicon carbonitride (SiCₓN_{y}), aluminum oxide (AlOₓ), aluminum nitride (AlNₓ), tantalum oxide (TaOₓ), hafnium oxide (HfOₓ), zirconium oxide (ZrOₓ), titanium oxide (TiOₓ), or the like. These may be used alone or in combination with each other. The buffer layer BFL may have a single-layer structure or a multi-layer structure including a plurality of insulating layers. In an embodiment, the buffer layer BFL may be omitted.

The circuit element layer CEL may be disposed on the buffer layer BFL. In an embodiment, the circuit element layer CEL may include first to third insulating layers IL1, IL2, and IL3, a thin film transistor TR, and a capacitor. The thin film transistor TR may include an active layer ACT, a gate electrode GE, a source electrode SE, and a drain electrode DE.

The active layer ACT may be disposed on the buffer layer BFL. The active layer ACT may include an oxide semiconductor, a silicon semiconductor, an organic semiconductor, or the like. For example, the oxide semiconductor may include at least one selected from oxides of indium (In), gallium (Ga), tin (Sn), zirconium (Zr), vanadium (V), hafnium (Hf), cadmium (Cd), germanium (Ge), chromium (Cr), titanium (Ti), and zinc (Zn). The silicon semiconductor may include an amorphous silicon, a polycrystalline silicon, or the like. The active layer ACT may have a source area, a drain area, and a channel area between the source area and the drain area.

A first insulating layer IL1 may be disposed on the active layer ACT. The first insulating layer IL1 may cover the active layer ACT on the buffer layer BFL. The first insulating layer IL1 may include an inorganic insulating material.

The gate electrode GE may be disposed on the first insulating layer IL1. The gate electrode GE may overlap the channel area of the active layer ACT. The gate electrode GE may include a conductive material, such as a metal, an alloy, a conductive metal nitride, a conductive metal oxide, a transparent conductive material, or the like. For example, the gate electrode GE may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), alloys containing aluminum, alloys containing silver, alloys containing copper, alloys containing molybdenum, aluminum nitride (AlNₓ), tungsten nitride (WNₓ), titanium nitride (TiNₓ), chromium nitride (CrNₓ), tantalum nitride (TaNₓ), strontium ruthenium oxide (SrRuOₓ), zinc oxide (ZnOₓ), indium tin oxide (ITO), tin oxide (SnOₓ), indium oxide (InOₓ), gallium oxide (GaOₓ), indium zinc oxide (IZO), or the like. These may be used alone or in combination with each other. The gate electrode GE may have a single-layer structure or a multi-layer structure including a plurality of conductive layers.

A second insulating layer IL2 may be disposed on the gate electrode GE. The second insulating layer IL2 may cover the gate electrode GE on the first insulating layer IL1. The second insulating layer IL2 may include an inorganic insulating material.

The source electrode SE and the drain electrode DE may be disposed on the second insulating layer IL2. The source electrode SE and the drain electrode DE may be connected to the source area and the drain area of the active layer ACT, respectively. Each of the source electrode SE and the drain electrode DE may include a conductive material.

A third insulating layer IL3 may be disposed on the source electrode SE and the drain electrode DE. The third insulating layer IL3 may include an organic insulating material. For example, the third insulating layer IL3 may include a photoresist, a polyacryl-based resin, a polyimide-based resin, a polyamide-based resin, a siloxane-based resin, an acryl-based resin, an epoxy-based resin, or the like. These may be used alone or in combination with each other.

In the above, the circuit element layer CEL has been described as including three insulating layers, one active layer, and two conductive layers, but this is merely an example, and embodiments are not limited thereto. The number of insulating layers, the number of active layers, and the number of conductive layers included in the circuit element layer CEL may be variously changed.

The light emitting element layer LEL may be disposed on the circuit element layer CEL. In an embodiment, the light emitting element layer LEL may include a light emitting element LED and a pixel defining layer PDL. The light emitting element LED may include a first electrode ED1, an emitting layer EL, and a second electrode ED2.

The first electrode ED1 may be disposed on the third insulating layer IL3. The first electrode ED1 may include a conductive material. The first electrode ED1 may have a single-layer structure or a multi-layer structure including a plurality of conductive layers. In an embodiment, the first electrode ED1 may be connected to the drain electrode DE through a contact hole (e.g., a contact opening) defined or formed in the third insulating layer IL3. Accordingly, the first electrode ED1 may be electrically connected to the thin film transistor TR. The first electrode ED1 may be an anode.

The pixel defining layer PDL may be disposed on the first electrode ED1. The pixel defining layer PDL may cover a peripheral portion of the first electrode ED1 and may define a pixel opening exposing a central portion of the first electrode ED1. The pixel defining layer PDL may include an organic insulating material.

The emission layer EL may be disposed on the first electrode ED1. The emission layer EL may be disposed in the pixel opening of the pixel defining layer PDL. In some embodiments, the emission layer EL may include an organic light emitting material.

In an embodiment, the organic light emitting material may include a low molecular organic compound or a high molecular organic compound. Examples of the low molecular organic compound may include copper phthalocyanine, N,N′-diphenylbenzidine, tris-(8-hydroxyquinoline)aluminum, or the like. Examples of the high molecular organic compound may include poly(3,4-ethylenedioxythiophene), polyaniline, poly-phenylenevinylene, polyfluorene, or the like. These can be used alone or in a combination thereof.

The second electrode ED2 may be disposed on the emission layer EL. The second electrode ED2 may also be disposed on the pixel defining layer PDL. The second electrode ED2 may include a conductive material. The second electrode ED2 may be a cathode.

The first electrode ED1, the light emitting layer EL, and the second electrode ED2 may form the light emitting element LED. The light emitting element LED may further include various functional layers (e.g., a hole injection layer, a hole transport layer, an electron transport layer, an electron injection layer, or the like) disposed between the first electrode ED1 and the emission layer EL or between the emission layer EL and the second electrode ED2.

The encapsulation layer ENL may be disposed on the light emitting element layer LEL. The encapsulation layer ENL may include at least one inorganic encapsulation layer and at least one organic encapsulation layer. In an embodiment, the encapsulation layer ENL may include a first inorganic encapsulation layer IEL1 disposed on the second electrode ED2, an organic encapsulation layer OEL disposed on the first inorganic encapsulation layer IEL1, and a second inorganic encapsulation layer IEL2 disposed on the organic encapsulation layer OEL, but this is merely an example, and embodiments are not limited thereto. The organic encapsulation layer OEL may cover the entire display area DA. In some embodiments, the display panel 100 may further include various functional layers (e.g., a touch sensing layer, a color filter layer, a light collection layer, or the like) disposed on the encapsulation layer ENL.

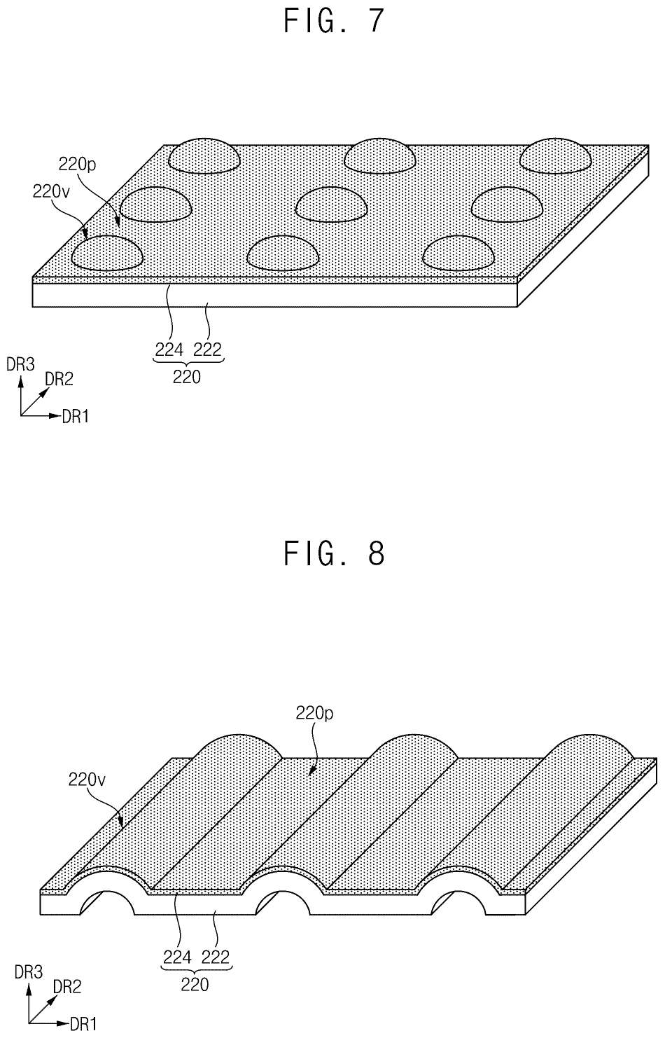

FIG. 6 is a cross-sectional view of a vapor chamber according to an embodiment.

Referring to FIG. 6, in an embodiment, the vapor chamber 200 may have a front surface member 210, a rear surface member 220, a wick 230, and a refrigerant.

The front surface member 210 and the rear surface member 220 may be coupled to each other to define an accommodation space in which the refrigerant may be disposed within the vapor chamber 200. In an embodiment, the rear surface member 220 may have a step portion 220s formed along an edge thereof. The step portion 220s of the rear surface member 220 may be coupled to an edge of the front surface member 210. However, this is merely an example, and embodiments are not limited thereto. According to various embodiments, the front surface member 210 and the rear surface member 220 may be coupled to each other in various ways.

The front surface member 210 may be flexible. In an embodiment, the front surface member 210 may include a first layer 212 and a second layer 214 including different materials from each other.

The first layer 212 may have a first surface 212a and a second surface 212b opposite to the first surface 212a. The second surface 212b may be positioned in the third direction DR3 from (or with respect to) the first surface 212a. The second surface 212b of the first layer 212 may be the front surface of the vapor chamber 200 and may face the second surface 100b of the display panel 100 as illustrated in, for example, FIG. 4. For example, the second surface 212b of the first layer 212 may be in contact with the second surface 100b of the display panel 100.

The first layer 212 may be flexible. In an embodiment, the first layer 212 may include a polymer or a composite material. For example, the first layer 212 may include a polymer resin, such as polycarbonate (PC), polyimide (PI), polyethylene terephthalate (PET), polyethersulphone (PES), polyethylene naphthalate (PEN), or the like, but embodiments are not limited thereto. In another embodiment, the first layer 212 may include a composite material, such as a carbon composite material, a metal composite material, a ceramic composite material, a fiber reinforced plastic (FRP), or the like. The carbon composite material may include at least one of graphite, carbon nanotubes (CNT), carbon fibers, or graphene. The metal composite material may include a polymer matrix and metal particles. The ceramic composite material may include a polymer matrix and ceramic particles. The fiber reinforced plastic may include a polymer matrix and at least one of glass fibers, carbon fibers, or metal fibers.

In an embodiment, a thickness of the first layer 212 in the third direction DR3 may be in a range of about 500 micrometers to about 1000 micrometers. When the thickness of the first layer 212 is less than about 500 micrometers, a stiffness (or rigidity) of the vapor chamber 200 in the third direction DR3 may be excessively reduced, and the vapor chamber 200 may be easily deformed in the third direction DR3. When the thickness of the first layer 212 is greater than about 1000 micrometers, the heat dissipation performance of the vapor chamber 200 may be reduced, and the flexibility of the vapor chamber 200 may be excessively reduced.

In an embodiment, the second layer 214 may include a metal or an alloy. For example, the second layer 214 may include aluminum, stainless steel, or the like, but embodiments are not limited thereto.

The second layer 214 may be disposed on (e.g., may cover) the entire first surface 212a of the first layer 212. For example, the second layer 214 may be coated entirely on the first surface 212a of the first layer 212. In some embodiments, the second layer 214 may be attached entirely on (e.g., may be attached to the entirety of) the first surface 212a of the first layer 212 by using an adhesive.

The polymer or the composite material of the first layer 212 may have relatively high permeability to non-condensable gas (NCG). When the second layer 214 is omitted, NCG may flow into the accommodation space of the vapor chamber 200 from outside of the vapor chamber 200 through the first layer 212, which causes the heat dissipation performance of the vapor chamber 200 to be reduced. By disposing the second layer 214 including a metal or an alloy on the first surface 212a of the first layer 212, NCG may be prevented from flowing into the accommodation space of the vapor chamber 200 from outside of the vapor chamber 200. Therefore, the heat dissipation performance of the vapor chamber 200 may be maintained or may not be reduced. In addition, the metal or the alloy included in the second layer 214 may have relatively higher wettability than the polymer or the composite material included in the first layer 212. Accordingly, a capillary force inside the vapor chamber 200 may be increased, and two phase flow of the refrigerant may be promoted. Therefore, the heat dissipation performance of the vapor chamber 200 may be improved. Accordingly, the reliability of the display device 10 may be improved.

The second layer 214 may be flexible. The second layer 214 including a metal or an alloy may have a relatively thin thickness in the third direction DR3 so that it may be flexible. The thickness of the second layer 214 in the third direction DR3 may be less than the thickness of the first layer 212 in the third direction DR3.

In an embodiment, the thickness of the second layer 214 in the third direction DR3 may be in a range of about 10 micrometers to about 200 micrometers. When the thickness of the second layer 214 is less than about 10 micrometers, the second layer 214 may be easily separated from the first layer 212. When the thickness of the second layer 214 is greater than about 200 micrometers, the flexibility of the vapor chamber 200 may be excessively reduced.

The rear surface member 220 may be positioned in the direction opposite to the third direction DR3 (e.g., the rear direction) from the front surface member 210. The rear surface member 220 may be flexible. In an embodiment, the rear surface member 220 may include a third layer 222 and a fourth layer 224 including different materials from each other.

The third layer 222 may have a first surface 222a and a second surface 222b opposite to the first surface 222a. The first surface 222a may be positioned in the third direction DR3 from (or with respect to) the second surface 222b. The second surface 222b of the third layer 222 may be the rear surface of the vapor chamber 200 and may face the driving board 300 as illustrated in, for example, FIG. 4.

The third layer 222 may be flexible. In an embodiment, the third layer 222 may include a polymer or composite material. For example, the third layer 222 may include the same material as the first layer 212.

In an embodiment, the thickness of the third layer 222 in the third direction DR3 may be in a range of about 500 micrometers to about 1000 micrometers.

The fourth layer 224 may be disposed on the first surface 222a of the third layer 222. The fourth layer 224 may have a first surface 224a and a second surface 224b opposite to the first surface 224a. The second surface 224b may be positioned in the third direction DR3 from (or with respect to) the first surface 224a. The first surface 224a of the fourth layer 224 may face the third layer 222. For example, the first surface 224a of the fourth layer 224 may be in contact with the first surface 222a of the third layer 222. In another embodiment, an adhesive may be disposed between the third layer 222 and the fourth layer 224. The second surface 224b of the fourth layer 224 may face the wick 230.

In an embodiment, the fourth layer 224 may include a metal or an alloy. For example, the fourth layer 224 may include the same material as the second layer 214.

The fourth layer 224 may be disposed on the entire first surface 222a of the third layer 222. For example, the fourth layer 224 may be coated entirely on the first surface 222a of the third layer 222. In another embodiment, the fourth layer 224 may be attached entirely on (e.g., may be attached to cover the entirely of) the first surface 222a of the third layer 222 by using an adhesive.

The fourth layer 224 may be flexible. The fourth layer 224 including a metal or an alloy may have a relatively thin thickness in the third direction DR3 so that it may be flexible. The thickness of the fourth layer 224 in the third direction DR3 may be less than the thickness of the third layer 222 in the third direction DR3. In an embodiment, the thickness of the fourth layer 224 in the third direction DR3 may be in a range of about 10 micrometers to about 200 micrometers.

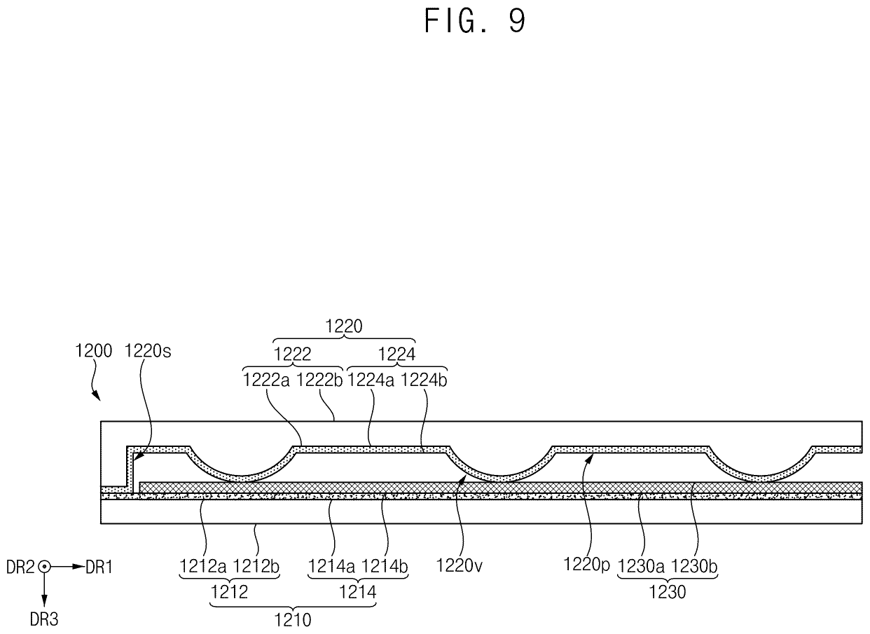

In an embodiment, the rear surface member 220 may have a convex portion 220v. This will be described, in detail, later with reference to FIGS. 7 and 8.

The wick 230 may be positioned between the front surface member 210 and the rear surface member 220. The wick 230 may be positioned between the second layer 214 and the fourth layer 224. The wick 230 may have a first surface 230a and a second surface 230b opposite to the first surface 230a. The first surface 230a may be positioned in the third direction DR3 from (or with respect to) the second surface 230b.

In an embodiment, the wick 230 may be disposed on one surface of the front surface member 210. The wick 230 may be disposed on the second surface 214b of the second layer 214. For example, the first surface 230a of the wick 230 may be in contact with the second surface 214b of the second layer 214. For example, the wick 230 may be disposed over the entire area at where the front surface member 210 overlaps the display panel 100.

The wick 230 may be a wick structure having a capillary tube structure. The wick 230 may generate a capillary phenomenon to cause the refrigerant positioned at a lower portion of the wick 230 to rise in a direction opposite to a direction of gravity.

The refrigerant may be positioned inside the vapor chamber 200 in a liquid state or a gas state. The refrigerant may at least partially fill the accommodation space between the front surface member 210 and the rear surface member 220. The refrigerant may include a phase change material (PCM). The refrigerant may absorb heat from a contact object (e.g., from an object in contact with the refrigerant) while vaporizing and may dissipate the heat to the surroundings (e.g., to the outside) while condensing.

The refrigerant may move along the wick 230 while in the liquid state and may be positioned on (e.g., may cover) the entire second surface 214b of the second layer 214 of the front surface member 210. When the heat generated by the display panel 100 is transferred to the front surface member 210, the refrigerant in the wick 230 may vaporize.

The refrigerant in the gas state may circulate inside the vapor chamber 200 and may condense on the second surface 224b of the fourth layer 224 of the rear surface member 220, which has a relatively low temperature. The refrigerant may dissipate the heat to a place that does not overlap the display panel 100 in a plan view while condensing. Accordingly, the vapor chamber 200 may dissipate the heat generated from the display panel 100.

FIGS. 7 and 8 are perspective views illustrating a rear surface member included in the vapor chamber shown in FIG. 6 according to various embodiments.

Referring to FIGS. 6 to 8, in various embodiments, the rear surface member 220 may include a plurality of convex portions 220v and a flat portion 220p between adjacent convex portions 220v. Each of the convex portions 220v may be convex toward the wick 230 (e.g., in the third direction DR3) from the flat portion 220p.

In an embodiment, the first surface 222a of the third layer 222 may have a flat portion 220p and convex portions 220v that are convex in the third direction DR3 from the flat portion 220p. The fourth layer 224 may be disposed along a profile of the first surface 222a of the third layer 222. For example, the thickness of the fourth layer 224 in the third direction DR3 may be substantially uniform.

Because the rear surface member 220 includes the convex portions 220v, the second surface 224b of the fourth layer 224 may partially contact the second surface 230b of the wick 230. Accordingly, the stiffness (or rigidity) of the vapor chamber 200 in the third direction DR3 may be improved, and deformation of the vapor chamber 200 in the third direction DR3 due to a pressure difference between the inside and the outside of the vapor chamber 200 may be prevented or reduced. Accordingly, the reliability of the vapor chamber 200 and the display device 10 including the same may be improved.

In an embodiment, as illustrated in FIGS. 6 and 7, each of the convex portions 220v may have a half-spherical shape or an elliptical (oval-shaped) half-spherical shape that is convex in the third direction DR3. For example, each of the convex portions 220v may have a dome shape that is convex in the third direction DR3. For example, the convex portions 220v may be spaced apart from each other in the first direction DR1 and the second direction DR2.

When each of the convex portions 220v has a half-spherical shape or an elliptical half-spherical shape that is convex in the third direction DR3, the fourth layer 224 may be in point contact with the wick 230. Therefore, compared to an embodiment in which the fourth layer 224 is in surface contact with the wick 230, the vapor chamber 200 may be more easily bent in directions perpendicular to the third direction DR3 (e.g., the first direction DR1 and/or the second direction DR2). Therefore, the vapor chamber 200 may be attached to the entire display panel 100 without an air gap by a lamination process using a roller, or the like. In addition, compared to an embodiment in which each of the convex portions 220v has a circular cone shape protruding in the third direction DR3, damage to the wick 230 by the fourth layer 224 when the vapor chamber 200 is bent can be reduced.

In an embodiment, as illustrated in FIGS. 6 and 8, each of the convex portions 220v may have a half-cylindrical shape or an elliptical half-cylindrical shape that is convex in the third direction DR3. For example, each of the convex portions 220v may extend in the second direction DR2. The convex portions 220v may be spaced apart from each other in the first direction DR1.

When each of the convex portions 220v has a half-cylindrical shape or an elliptical half-cylindrical shape that is convex in the third direction DR3, the fourth layer 224 may be in line contact with the wick 230. Therefore, compared to an embodiment in which the fourth layer 224 is in surface contact with the wick 230, the vapor chamber 200 may be easily bent in one direction perpendicular to the third direction DR3 (e.g., the first direction DR1). Even when the vapor chamber 200 is easily bent only in one direction, the vapor chamber 200 may be attached to the entire display panel 100 without an air gap by a lamination process using a roller, or the like. In addition, compared to an embodiment in which the fourth layer 224 is in point contact with the wick 230, the stiffness (or rigidity) of the vapor chamber 200 in the third direction DR3 may be further improved.

In an embodiment, as illustrated in FIG. 6, the second surface 222b of the third layer 222 may have a flat portion and concave portions 220c. The concave portions 220c may correspond to the convex portions 220v, respectively. Each of the concave portions 220c may be concave toward the first surface 222a of the third layer 222 (e.g., in the third direction DR3) from the flat portion. For example, the second surface 222b of the third layer 222 may be curved (e.g., not flat).

For example, the rear surface member 220 including the third layer 222 and the fourth layer 224 coated on the third layer 222 may be partially pressed in the third direction DR3 by a pressing process, and the convex portions 220v that are convex in the third direction DR3 may be easily formed. In such an embodiment, the second surface 222b of the third layer 222 may be curved to include the flat portion and the concave portions 220c. Because the second surface 222b of the third layer 222 is not a surface attached to the display panel 100, it may be curved without issue.

The second surface 212b of the first layer 212 of the front surface member 210 may be flat. The second surface 212b of the first layer 212 of the front surface member 210, which is the surface attached to the rear surface of the display panel 100, should be flat to be attached to the rear surface of the display panel 100 without an air gap.

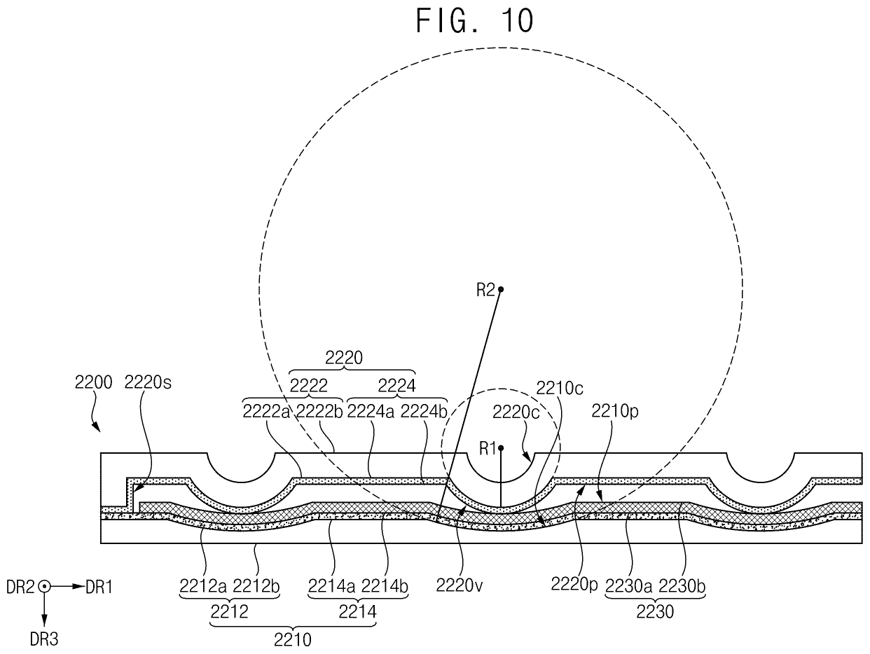

FIG. 9 is a cross-sectional view of a vapor chamber according to another embodiment.

Referring to FIG. 9, in an embodiment, the vapor chamber 1200 may include a front surface member 1210, a rear surface member 1220, a wick 1230, and a refrigerant. The front surface member 1210 may include a first layer 1212 and a second layer 1214. The rear surface member 1220 may include a third layer 1222 and a fourth layer 1224.

The vapor chamber 1200 shown in FIG. 9 may be substantially same as or similar to the vapor chamber 200 described above with reference to FIG. 6 except that a second surface 1222b of the third layer 1222 of the rear surface member 1220, which is a rear surface of the vapor chamber 1200, is flat. Therefore, repeated descriptions of the vapor chamber 1200 may be omitted or simplified.

In an embodiment, the third layer 1222, which includes a polymer or composite material and has a first surface 1222a that is curved to have a flat portion and convex portions and a second surface 1222b that is flat, may be manufactured by injection molding. Then, the fourth layer 1224, which includes a metal or alloy, may be formed on the first surface 1222a of the third layer 1222, thereby forming the rear surface member 1220.

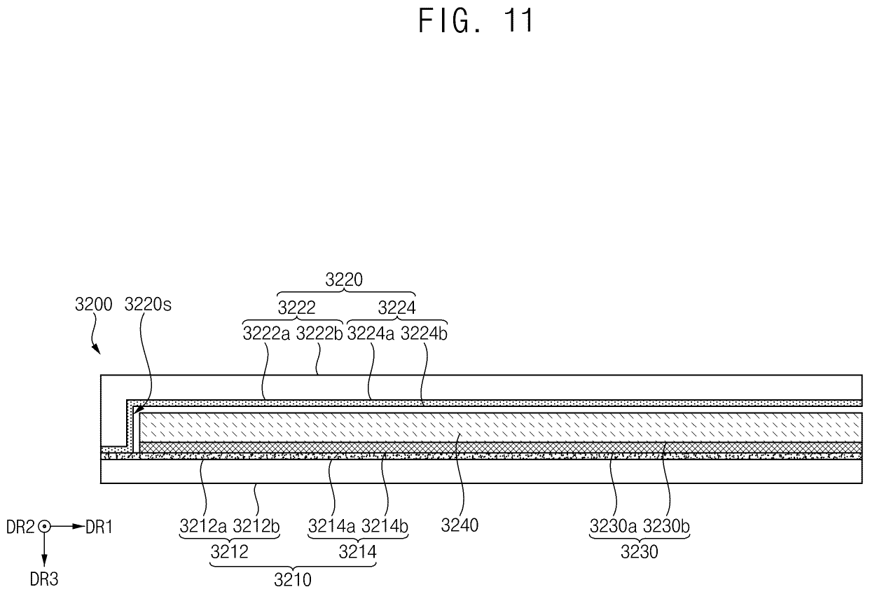

FIG. 10 is a cross-sectional view of a vapor chamber according to another embodiment.

Referring to FIG. 10, in an embodiment, the vapor chamber 2200 may include a front surface member 2210, a rear surface member 2220, a wick 2230, and a refrigerant. The front surface member 2210 may include a first layer 2212 and a second layer 2214. The rear surface member 2220 may include a third layer 2222 and a fourth layer 2224.

The vapor chamber 2200 shown in FIG. 10 may be substantially same as or similar to the vapor chamber 200 described above with reference to FIG. 6 except that the front surface member 2210 has a plurality of concave portions 2210c. Therefore, repeated descriptions of the vapor chamber 2200 may be omitted or simplified.

The rear surface member 2220 may have a plurality of convex portions 2220v and a flat portion 2220p between adjacent convex portions 2220v. Each of the convex portions 2220v may be convex toward the wick 2230 (e.g., in the third direction DR3) from (or with respect to) the flat portion 2220p.

In an embodiment, a first surface 2222a of the third layer 2222 may have a flat portion and convex portions that is convex in the third direction DR3 from the flat portion. The fourth layer 2224 may be disposed along a profile of the first surface 2222a of the third layer 2222. For example, a thickness of the fourth layer 2224 in the third direction DR3 may be substantially uniform.

The front surface member 2210 may have a plurality of concave portions 2210c and a flat portion 2210p between adjacent concave portions 2210c. The concave portions 2210c of the front surface member 2210 may correspond to the convex portions 2220v of the rear surface member 2220, respectively. Each of the concave portions 2210c may be concave in the third direction DR3 from (or with respect to) the flat portion 2210p.

In an embodiment, a first surface 2212a of the first layer 2212 may have a flat portion and concave portions that are concave in the third direction DR3 from (or with respect to) the flat portion. The second layer 2214 and the wick 2230 may be disposed along a profile of the first surface 2212a of the first layer 2212. For example, a thickness of each of the second layer 2214 and the wick 2230 in the third direction DR3 may be substantially uniform. Accordingly, a second surface 2230b of the wick 2230, which is partially in contact with (e.g., which partially contacts) a second surface 2224b of the fourth layer 2224, may be concavely curved in the third direction DR3 in an area overlapping the convex portion 2220v.

In an embodiment, as illustrated in FIG. 10, a curvature radius R1 of each of the convex portions 2220v of the rear surface member 2220 may be less than a curvature radius R2 of each of the concave portions 2210c of the front surface member 2210. For example, the curvature radius R1 of each of the convex portions 2220v may a curvature radius of the convex portion defined by the first surface 2222a of the third layer 2222, and the curvature radius R2 of each of the concave portions 2210c may be a curvature radius of the concave portion defined by the first surface 2212a of the first layer 2212.

In an embodiment, each of the concave portions 2210c of the front surface member 2210 may have a shape corresponding to a shape of each of the convex portions 2220v of the rear surface member 2220. For example, as illustrated in FIG. 7, when each of the convex portions 2220v of the rear surface member 2220 has a half-spherical shape or an elliptical half-spherical shape that is convex in the third direction DR3, each of the concave portions 2210c of the front surface member 2210 may be a groove having a half-spherical shape or an elliptical half-spherical shape that is concave in the third direction DR3. For another example, as illustrated in FIG. 8, when each of the convex portions 2220v of the rear surface member 2220 has a half-cylindrical shape or an elliptical half-cylindrical shape that extends in the second direction DR2 and is convex in the third direction DR3, each of the concave portions 2210c of the front surface member 2210 may be a groove having a half-spherical shape or an elliptical half-spherical shape that extends in the second direction DR2 and is concave in the third direction DR3.

If the front surface member 2210 does not have the concave portions 2210c, when the vapor chamber 2200 is bent and then straightened, a portion (e.g., a contact portion) of the fourth layer 2224, which is in contact with the second surface 2230b of the wick 2230, may contact the second surface 2230b of the wick 2230 at a position different from a previous contact position at where the contact portion is in contact with the second surface 2230b before the vapor chamber 2200 is bent. For example, during the bending or straightening of the vapor chamber 2200, the front surface member 2210 and the rear surface member 2220 may be twisted.

According to the embodiment shown in FIG. 10, the front surface member 2210 may have the concave portions 2210c corresponding to the convex portions 2220v of the rear surface member 2220. Therefore, when the vapor chamber 2200 is bent or straightened, the contact portion of the fourth layer 2224 may easily move (e.g., slip) on the second surface 2230b of the wick 2230. Accordingly, when the vapor chamber 2200 is bent and then straightened, the contact portion of the fourth layer 2224 may easily move (e.g., return) to the previous contact position at where the contact portion is in contact with the second surface 2230b before the vapor chamber 2200 is bent. For example, during the bending or straightening of the vapor chamber 2200, twisting of the front surface member 2210 and the rear surface member 2220 may be prevented or reduced.

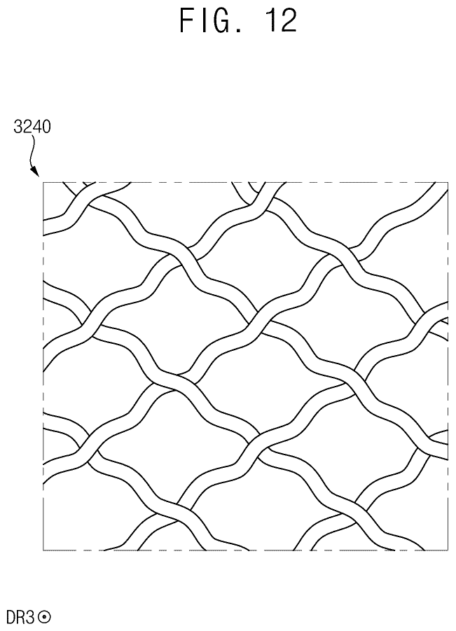

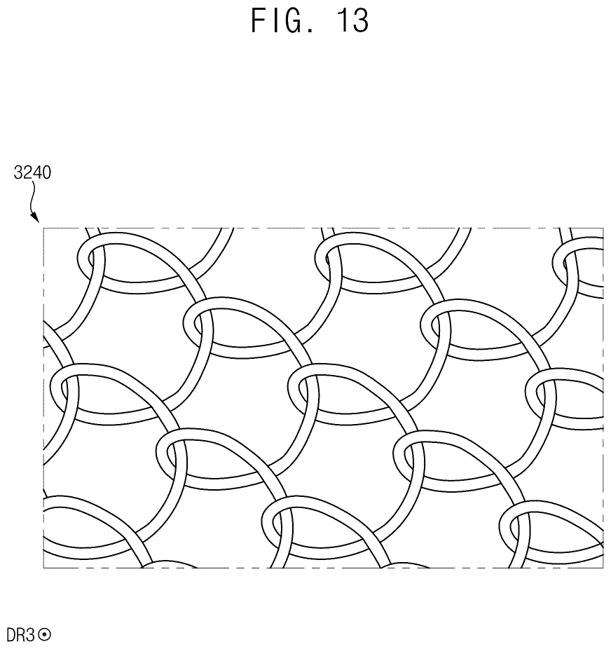

FIG. 11 is a cross-sectional view of a vapor chamber according to another embodiment. FIGS. 12 and 13 are views of a reinforcing member included in the vapor chamber shown in FIG. 11 according to various embodiments.

Referring to FIG. 11, in an embodiment, the vapor chamber 3200 may include a front surface member 3210, a rear surface member 3220, a wick 3230, a refrigerant, and a reinforcing member 3240. The front surface member 3210 may include a first layer 3212 and a second layer 3214. The rear surface member 3220 may include a third layer 3222 and a fourth layer 3224.

The vapor chamber 3200 shown in FIG. 11 may be substantially same as or similar to the vapor chamber 200 described above with reference to FIG. 6 except that the rear surface member 3220 does not have convex portions and the reinforcing member 3240 is disposed between the front surface member 3210 and the rear surface member 3220. Therefore, repeated descriptions of the vapor chamber 3200 may be omitted or simplified.

In an embodiment, the reinforcing member 3240 may be disposed between the front surface member 3210 and the rear surface member 3220. For example, as illustrated in FIG. 11, the reinforcing member 3240 may be disposed between the wick 3230 and the rear surface member 3220. In another embodiment, the reinforcing member 3240 may be disposed between the wick 3230 and the front surface member 3210. In another embodiment, the vapor chamber 3200 may include a first wick disposed on a second surface 3214b of the second layer 3214 and a second wick disposed on a second surface 3224b of the fourth layer 3224, and the reinforcing member 3240 may be disposed between the first wick and the second wick.

The reinforcing member 3240 may be flexible. The reinforcing member 3240 may reinforce the stiffness (or rigidity) of the vapor chamber 3200 in the third direction DR3. In an embodiment, the reinforcing member 3240 may include a wire mesh. For example, the reinforcing member 3240 may include a metal or an alloy.

In an embodiment, as illustrated in FIG. 12, the reinforcing member 3240 may include (or may be) a crimped wire mesh in which wavy wires are alternately woven. The crimped wire mesh may have a relatively large stiffness (or rigidity) in the third direction DR3, which is a vertical direction.

In another embodiment, as illustrated in FIG. 13, the reinforcing member 3240 may include (or may be) a spiral wire mesh in which spiral wires are alternately woven. The spiral wire mesh may have a relatively small stiffness (or rigidity) in the third direction DR3, which is the vertical direction, but may have a relatively good flexibility in the first direction DR1 and/or the second direction DR2, which is a horizontal direction(s).

However, these are examples, and embodiments are not limited thereto. The reinforcing member 3240 may include other structures, materials, or the like that may reinforce stiffness (or rigidity) in the third direction DR3 and may also secure flexibility in the first direction DR1 and/or the second direction DR2.

In an embodiment, when the reinforcing member 3240 may sufficiently secure stiffness (or rigidity) in the third direction DR3, in at least one of the front surface member 3210 and the rear surface member 3220, a layer including a polymer or composite material (e.g., the first layer 3212 or the third layer 3222) may be omitted. In such an embodiment, at least one of the front surface member 3210 and the rear surface member 3220 may be formed as a single layer (e.g., the second layer 3214 or the fourth layer 3224) including a metal or an alloy and having a relatively small thickness to be flexible.

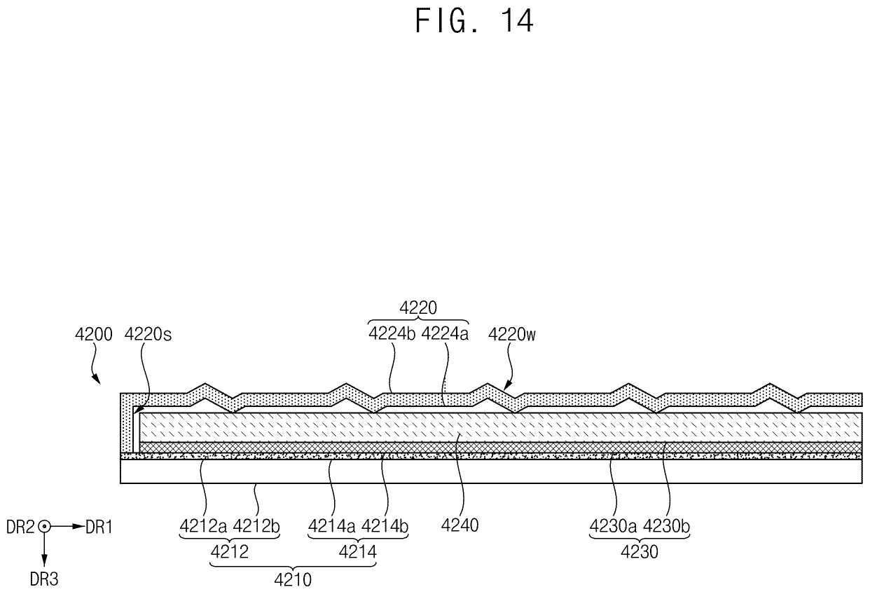

FIG. 14 is a cross-sectional view of a vapor chamber according to another embodiment.

Referring to FIG. 14, in an embodiment, the vapor chamber 4200 may include a front surface member 4210, a rear surface member 4220, a wick 4230, a refrigerant, and a reinforcing member 4240. The front surface member 4210 may include a first layer 4212 and a second layer 4214.

The vapor chamber 4200 shown in FIG. 12 may be substantially same as or similar to the vapor chamber 3200 described above with reference to FIG. 11 except that the rear surface member 4220 is formed as a single layer. Therefore, repeated descriptions of the vapor chamber 4200 may be omitted or simplified.

In an embodiment, the front surface member 4210 may include the first layer 4212 and the second layer 4214. The first layer 4212 may include a polymer or composite material. The second layer 4214 may include a metal or an alloy.

A thickness of the second layer 4214 in the third direction DR3 may be less than a thickness of the first layer 4212 in the third direction DR3. In an embodiment, the thickness of the first layer 4212 in the third direction DR3 may be in a range of about 500 micrometers to about 1000 micrometers. In an embodiment, the thickness of the second layer 4214 in the third direction DR3 may be in a range of about 10 micrometers to about 200 micrometers.

The rear surface member 4220 may be formed as a single layer. In an embodiment, the rear surface member 4220 may include a metal or an alloy. For example, the rear surface member 4220 may include the same material as the second layer 4214 of the front surface member 4210. For example, the rear surface member 4220 may include aluminum, stainless steel, or the like, but embodiments are not limited thereto.

The rear surface member 4220 may have a relatively large thickness to secure stiffness (or rigidity) in the third direction DR3 without a layer including a polymer or composite layer. In an embodiment, the thickness of the rear surface member 4220 in the third direction DR3 may be greater than the thickness of the second layer 4214 of the front surface member 4210 in the third direction DR3. For example, the thickness of the rear surface member 4220 in the third direction DR3 may be in a range of about 200 micrometers to about 1000 micrometers.

In an embodiment, the rear surface member 4220 may have a plurality of wrinkled portions 4220w. For example, each of the wrinkled portions 4220w may extend in the second direction DR2. The wrinkled portions 4220w may be spaced apart from each other in the first direction DR1. Because the rear surface member 4220 has the wrinkled portions 4220w, even when the rear surface member 4220 including a metal or an alloy has a relatively large thickness, the vapor chamber 4200 may be easily bent in one direction (e.g., the first direction DR1) perpendicular to the third direction DR3. Even when the vapor chamber 4200 is easily bent only in one direction, the vapor chamber 4200 may be attached to the entire display panel 100 without an air gap by a lamination process using a roller, or the like. Accordingly, because stiffness (or rigidity) and flexibility may be sufficiently secured even when the rear surface member 4220 is formed as a single layer, the manufacturing cost of the vapor chamber 4200 and the display device including the same may be reduced.

The rear surface member 4220 may have a first surface 4220a and a second surface 4220b opposite to the first surface 4220a. The second surface 4220b may be positioned in the third direction DR3 from (or with respect to) the first surface 4220a. The first surface 4220a of the rear surface member 4220 may face the reinforcing member 4240. The second surface 4220b of the rear surface member 4220 may be a rear surface of the vapor chamber 4200 and may face the driving board 300 as illustrated in, for example, FIG. 4.

Because the rear surface member 4220 has the wrinkled portions 4220w, each of the first surface 4220a and the second surface 4220b of the rear surface member 4220 may be curved. Because each of the first surface 4220a and the second surface 4220b of the rear surface member 4220 is not a surface attached to the display panel 100, they may be curved without issue.

The second surface 4212b of the first layer 4212 of the front surface member 4210 may be flat. The second surface 4212b of the first layer 4212 of the front surface member 4210, which is the surface attached to the rear surface of the display panel 100, should be flat to be attached to the rear surface of the display panel 100 without an air gap. Therefore, the front surface member 4210 may be difficult to form as a single layer including a metal or an alloy and having wrinkled portions.

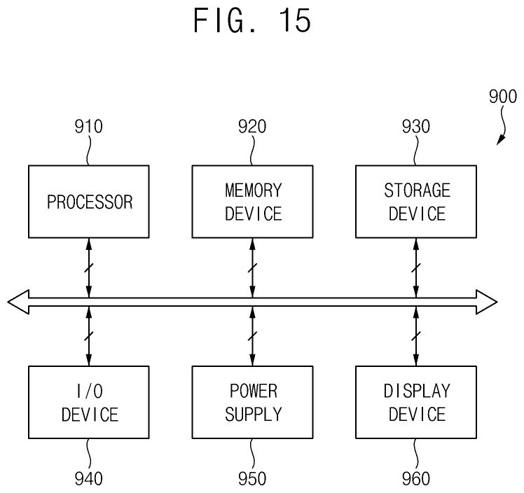

FIG. 15 is a block diagram describing an electronic device according to an embodiment.

Referring to FIG. 15, in an embodiment, an electronic device 900 may include a processor 910, a memory device 920, a storage device 930, an input/output (I/O) device 940, a power supply 950, and a display device 960. The display device 960 may correspond to the display device 10 described above. The electronic device 900 may further include a plurality of ports for communicating with a video card, a sound card, a memory card, a universal serial bus (USB) device, or the like. In an embodiment, the electronic device 900 may be implemented as a television. However, embodiments are not limited thereto, and in another embodiment, the electronic device 900 may be implemented as a tablet personal computer (PC), a car navigation system, a computer monitor, a laptop, a head mounted display (HMD), a cellular phone, a video phone, a smart pad, a smart watch, or the like.

The processor 910 may perform various computing functions. In an embodiment, the processor 910 may be a microprocessor, a central processing unit (CPU), an application processor (AP), or the like. The processor 910 may be coupled to other components via an address bus, a control bus, a data bus, or the like. In an embodiment, the processor 910 may be coupled to an extended bus such as a peripheral component interconnection (PCI) bus.

The memory device 920 may store data for operations of the electronic device 900. In an embodiment, the memory device 920 may include at least one non-volatile memory device, such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, a ferroelectric random access memory (FRAM) device, or the like, and/or at least one volatile memory device, such as a dynamic random access memory (DRAM) device, a static random access memory (SRAM) device, a mobile DRAM device, or the like.

In an embodiment, the storage device 930 may include a solid state drive (SSD) device, a hard disk drive (HDD) device, a CD-ROM device, or the like. In an embodiment, the I/O device 940 may include an input device, such as a keyboard, a keypad, a mouse device, a touchpad, a touch-screen, or the like, and an output device, such as a printer, a speaker, or the like.

The power supply 950 may provide power for operations of the electronic device 900. The power supply 950 may provide power to the display device 960. The display device 960 may be coupled to other components via the buses or other communication links. In an embodiment, the display device 960 may be included in the I/O device 940.

Although embodiments and implementations of the present disclosure have been described herein, other embodiments and modifications will be apparent from this description. Accordingly, the present disclosure is not limited to the described embodiments but, rather, to the broader scope of the appended claims and various equivalent arrangements as would be apparent to a person of ordinary skill in the art.

What is claimed is:

1. A vapor chamber comprising:
a front surface member comprising a first layer and a second layer on a first surface of the first layer, the second layer comprising a material different from a material of the first layer;
a rear surface member coupled to the front surface member and comprising a third layer and a fourth layer, the third layer having a first surface facing a first surface of the first layer, the fourth layer being on the first surface of the third layer and comprising a material different from a material of the third layer;
a wick between the front surface member and the rear surface member; and
a refrigerant at least partially filling an area between the front surface member and the rear surface member.

2. The vapor chamber of claim 1, wherein a thickness of the second layer is less than a thickness of the first layer, and
wherein a thickness of the fourth layer is less than a thickness of the third layer.

3. The vapor chamber of claim 1, wherein each of the first layer and the third layer comprises a polymer or a composite material, and
wherein each of the second layer and the fourth layer comprises a metal or an alloy.

4. The vapor chamber of claim 1, wherein the first surface of the third layer has a flat portion and a convex portion convex toward the wick from the flat portion.

5. The vapor chamber of claim 4, wherein the fourth layer extends along a profile of the first surface of the third layer.

6. The vapor chamber of claim 4, wherein the fourth layer is in point contact with the wick.

7. The vapor chamber of claim 6, wherein the convex portion has a half-spherical shape or an elliptical half-spherical shape convex toward the wick.

8. The vapor chamber of claim 4, wherein the fourth layer is in line contact with the wick.

9. The vapor chamber of claim 8, wherein the convex portion has a half-cylindrical shape or an elliptical half-cylindrical shape convex toward the wick.

10. The vapor chamber of claim 4, wherein the third layer has a second surface opposite to the first surface, and
wherein the second surface of the third layer has a flat portion and a concave portion that is concave toward the first surface of the third layer from the flat portion corresponding to the convex portion.

11. The vapor chamber of claim 4, wherein the third layer has a second surface opposite to the first surface, and
wherein the second surface of the third layer is flat.

12. The vapor chamber of claim 4, wherein the first layer has a second surface opposite to the first surface, and
wherein the first surface of the first layer has a flat portion and a concave portion concave toward the second surface of the first layer from the flat portion corresponding to the convex portion of the third layer.

13. The vapor chamber of claim 12, wherein a curvature radius of the convex portion of the third layer is less than a curvature radius of the concave portion of the first layer.

14. The vapor chamber of claim 12, wherein each of the second layer and the wick extends along a profile of the first surface of the first layer.

15. The vapor chamber of claim 12, wherein the first layer has a second surface opposite to the first surface, and
wherein the second surface of the first layer is flat.

16. The vapor chamber of claim 1, further comprising a reinforcing member between the wick and the rear surface member, the reinforcing member comprising a wire mesh.

17. A vapor chamber comprising:
a front surface member comprising a first layer and a second layer on the first layer, the second layer comprising a material different from a material of the first layer;
a rear surface member coupled to the front surface member and comprising a metal or an alloy, the rear surface member having wrinkled portions, the wrinkled portions each extending a first direction and arranged along a second direction perpendicular to the first direction;
a wick between the front surface member and the rear surface member;
a reinforcing member between the wick and the rear surface member; and
a refrigerant at least partially filling an area between the front surface member and the rear surface member.

18. The vapor chamber of claim 17, wherein the second layer comprises a metal or an alloy, and
wherein a thickness of the rear surface member is greater than a thickness of the second layer.

19. The vapor chamber of claim 17, wherein the first layer has a first surface facing the rear surface member and a second surface opposite to the first surface,
wherein the rear surface member has a first surface facing the front surface member and a second surface opposite to the first surface,
wherein the second surface of the first layer is flat, and
wherein each of the first surface and the second surface of the rear surface member is curved.

20. An electronic device comprising:
a display device comprising a display panel and a vapor chamber, the display panel having a first surface for displaying an image and a second surface opposite to the first surface, the vapor chamber being on the second surface of the display panel; and
a power supply configured to provide power to the display device,
wherein the vapor chamber comprises:
a front surface member comprising a first layer and a second layer on a first surface of the first layer, the second layer comprising a material different from a material of the first layer;
a rear surface member coupled to the front surface member and comprising a third layer and a fourth layer, the third layer having a first surface facing the first surface of the first layer, the fourth layer being on the first surface of the third layer and comprising a material different from a material of the third layer;
a wick between the front surface member and the rear surface member; and
a refrigerant at least partially filling an area between the front surface member and the rear surface member.
